(19) United States
(12) Patent Application Publication
(10) Pub. No.: US 2016/0174394 A1
(43) Pub. Date: Jun. 16, 2016

(54) PLUGGABLE OPTICAL COMMUNICATIONS MODULE HAVING AN IMPROVED LATCHING/DELATCHING MECHANISM, AND AN OPTICAL COMMUNICATIONS ASSEMBLY THAT INCLUDES THE MODULE

(71) Applicant: Avago Technologies General IP (Singapore) Pte. Ltd., Singapore (SG)

(72) Inventor: Chi Keung Lee, Palo Alto, CA (US)

(73) Assignee: Avago Technologies General IP (Singapore) Pte. Ltd., Singapore (SG)

(21) Appl. No.: 14/230,025

(22) Filed: Mar. 31, 2014

(51) Int. Cl. H05K 5/00

(52) U.S. Cl. CPC H05K 5/0073

(57) ABSTRACT

An optical communications module having an improved latching/delatching mechanism is provided. The slider arms of the latching/delatching mechanism are partially encased in the module housing. Partially encasing the slider arms in the module housing provides the latching/delatching mechanism with greater rigidity and eliminates the possibility of the latching/delatching mechanism becoming dislodged from the module housing due to excessive force being applied to the bail of the latching/delatching mechanism. In addition, the slider arms do not come into contact with the cage as the module housing is being inserted into and extracted from the cage. Distal portions of the slider arms remain outside of the module housing to allow hook features of the distal portions to disengage the cage latches during the delatching process.

### TECHNICAL FIELD OF THE INVENTION

The invention relates to pluggable optical communications modules. More particularly, the invention relates to a pluggable optical communications module having an improved latching/delatching mechanism.

### BACKGROUND OF THE INVENTION

One type of optical fiber cable is terminated on one or both ends with a pluggable optical communications module. The optical communications module is an optical receiver module, an optical transmitter module or an optical transceiver module. The connector module has a module housing that houses the electrical, optoelectronic and optical components of the module. Although various pluggable module designs exist, the module housing is typically configured to be plugged into an opening formed in a cage. Module housings of this type typically include a pair of cage latch stops formed on opposite outer side walls of the module housing that engage a pair of cage latches formed on opposite side walls of the cage to secure the module housing to the cage when the module housing is fully inserted into the cage. The pair of slider arms is part of a latching/delatching mechanism of the module housing. The latching/delatching mechanism also includes a bail that is rotatable by a user to allow it to be moved from a latched position into a delatching position. The bail is mechanically coupled to a yoke that is integrally formed with a pair of slider arms of the latching/delatching mechanism. The slider arms extend along opposite outer side walls of the module housing. The distal ends of the slider arms have respective hook features formed thereon that curve outwardly away from the respective outer side walls of the module housing.

When the module housing is fully inserted into the cage, the slider arms are positioned in between the respective outer side walls of the module housing and the respective inner side walls of the cage. Rotation of the bail into the delatching position pulls the slider arms along the respective outer side walls of the module housing in the direction toward the cage opening. As the slider arms move in this direction, the hook features on the distal ends of the arms press outwardly against the respective cage latches formed on the inner side walls of the cage, thereby causing the cage latches to disengage the respective cage latch stops formed in the opposite outer side walls of the module housing. The user then uses the bail as a handle to pull the module from the cage.

One of the disadvantages of the current latching/delatching mechanisms of the type described above relates to the manner in which the bail is secured to the module housing. Typically, opposite ends of the bail are secured to the module housing by press-fitted pins that are pressed through respective openings formed in the bail such that the ends of the bail are sandwiched in between the heads of the press-fitted pins and the outer side walls of the module housing. With this type of arrangement, forces exerted on the bail are transferred to the pins, and excessive forces can cause the pins to loosen, which can ultimately cause the latching/delatching mechanism to fail. Another disadvantage of latching/delatching mechanisms of this type is that the application of excessive force to the bail when attempting to extract the module from the cage can result in the latching/delatching mechanism becoming dislodged from the module housing.

Yet another disadvantage of latching/delatching mechanisms of this type is that the slider arms can cause the electromagnetic interference (EMI) gasket disposed about the cage opening to peel. The cage opening typically has an EMI gasket formed in or secured to the inner and outer top, bottom and side walls of the cage opening. The slider arms come into contact with the inner EMI gasket as the module housing is inserted into and retracted from the cage. This contact can cause the EMI gasket to peel, which can degrade the integrity of the gasket and result in improper EMI leakage from the cage.

Accordingly, a need exists for an optical communications module that has an improved latching/delatching mechanism that overcomes the above-described disadvantages.

### SUMMARY OF THE INVENTION

The invention is directed to a pluggable optical communications module and to an optical communications assembly that incorporates the module. The pluggable optical communications module comprises a module housing and a latching/delatching mechanism secured to the module housing. The module housing has a receptacle formed therein for receiving an end of an optical fiber cable. The module housing has at least a top, a bottom, a first side and a second side. The top and bottom are interconnected by the first and second sides such that the top, the bottom, the first side, and the second side form an encasement. Components of the module are housed in the encasement. The first and second sides have first and second cage latch stops thereon, respectively. The latching/delatching mechanism includes at least a bail and a slider. The bail is pivotally coupled with the module housing to allow the bail to rotate between a latched position and a delatched position.

The slider includes at least first and second slider arms and a yoke, which is joined with proximal ends of the first and second slider arms and is positioned to mechanically couple with the bail as the bail is pivoted from the latched position to the delatched position. The first slider arm extends along at least a portion of the first side of the module housing and is partially encased within the encasement. At least a distal end of the first slider arm is outside of the encasement. The second slider arm extends along at least a portion of the second side of the module housing and is partially encased within the encasement. At least a distal end of the second slider arm is outside of the encasement. The distal ends of the first and second slider arms include first and second hook features, respectively, that curve outwardly relative to the first and second sides, respectively, of the module housing.

In accordance with one embodiment, the first and second slider arms are partially encased by disposing them in first and second channel grooves, respectively, of the module housing. The first side of the module housing has a first inner side wall and a first outer side wall that are separated by a small gap to form the first channel groove. The second side of the module housing has a second inner side wall and a second outer side wall that are separated by a gap to form the second channel groove.

The optical communications assembly comprises a cage and an optical communications module disposed in an opening of the cage. The cage has a top, a bottom, a first side and a second side. The top and bottom of the cage are interconnected by the first and second sides of the cage such that the top, the bottom, the first side, and the second side of the cage define the cage opening. First and second cage latches are disposed on the first and second sides of the cage, respectively, within the opening. The pluggable optical communications module comprises a module housing and a latching/delatching mechanism secured to the module housing. The latching/delatching mechanism includes at least a bail and a slider. The bail is pivotally coupled with the module housing to allow the bail to rotate between a latched position and a delatched position. The slider includes at least first and second slider arms and a yoke. The yoke is joined with proximal ends of the first and second slider arms and is positioned to mechanically couple with the bail as the bail is pivoted from the latched position to the delatched position. The first slider arm extends along at least a portion of the first side of the module housing and is partially encased within the encasement. At least a distal end of the first slider arm is outside of the encasement. The second slider arm extends along at least a portion of the second side of the module housing and is partially encased within the encasement. At least a distal end of the second slider arm is outside of the encasement. The distal ends of the first and second slider arms include first and second hook features, respectively, that curve outwardly relative to the first and second sides, respectively, of the module housing.

These and other features and advantages of the invention will become apparent from the following description, drawings and claims.

### BRIEF DESCRIPTION OF THE DRAWINGS

FIGS. 1A and 1B illustrate perspective views of the optical communications module in accordance with an illustrative embodiment with the bail in the latched and delatched positions, respectively.

FIG. 2 illustrates a perspective view of the optical communications module shown in FIGS. 1A and 1B disassembled to show the bail, upper and lower housing portions of a module housing, a slider, and dowel pins.

FIGS. 3A and 3B illustrate perspective views of the upper housing portion 3a shown in FIG. 2 before and after, respectively, the bail 2, the slider 4 and the dowel pins 5a and 5b have been installed in the upper housing portion 3a.

FIGS. 4A-4C illustrate side plan views of the optical communications module shown in FIGS. 1A and 1B with the upper housing portion removed to reveal the manner in which the slider moves as the bail is moved from the latched position shown in FIG. 4C into the delatched position shown in FIG. 4C.

FIG. 5 illustrates a perspective view of the optical communications module shown in FIGS. 1A and 1B and a cage into which the module is about to be inserted mounted on a printed circuit board.

FIGS. 6A and 6B illustrate perspective views of the optical communications module installed in the cage shown in FIG. 5 with the bail in the latched and delatched positions, respectively.

### DETAILED DESCRIPTION OF AN EXEMPLARY EMBODIMENT

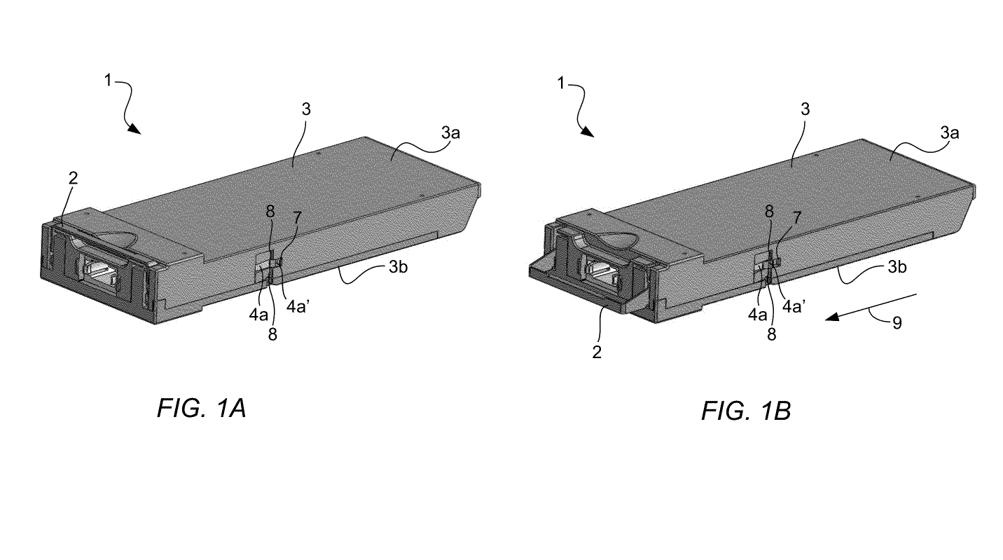

The invention is directed to an optical communications module having a latching/delatching mechanism that overcomes the foregoing disadvantages and that provides further advantages. The aforementioned problem of the slider arms coming into contact with the EMI gasket of the cage and potentially damaging the gasket is prevented by partially encasing the slider arms inside of the module housing. In this way, the slider arms do not come into contact with the cage as the module housing is being inserted into and extracted from the cage. The distal portions of the slider arms on which the hook features are formed remain outside of the module housing to allow them to come into contact with the cage latches during delatching. Additionally, partially encasing the slider arms in the module housing provides the latching/delatching mechanism with greater rigidity and eliminates the possibility of the latching/delatching mechanism becoming dislodged in the event that excessive force is applied to the bail when attempting to extract the module from the cage. Illustrative, or exemplary, embodiments will now be described with reference to FIGS. 1A-6B, in which like reference numerals identify like features, elements or components. It should be noted that features, elements or components shown in the drawings are not necessarily drawn to scale.

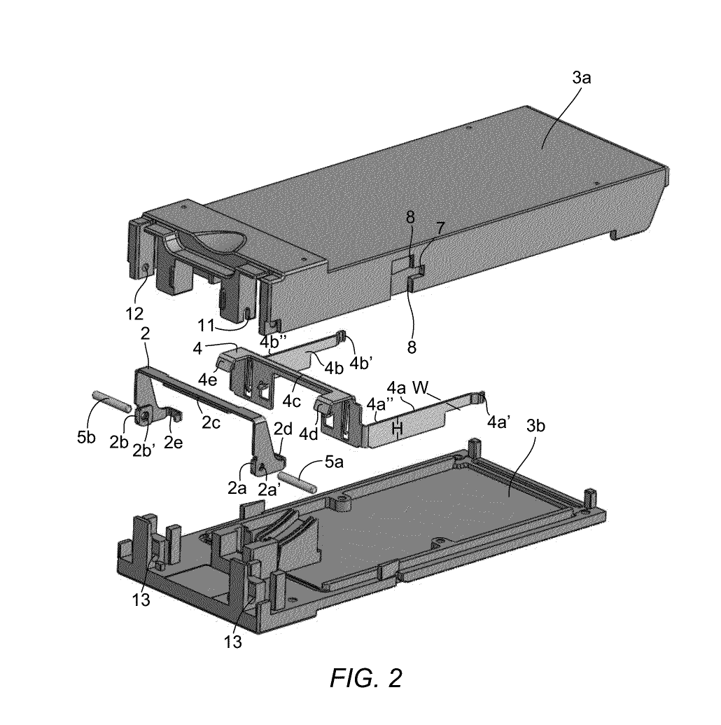

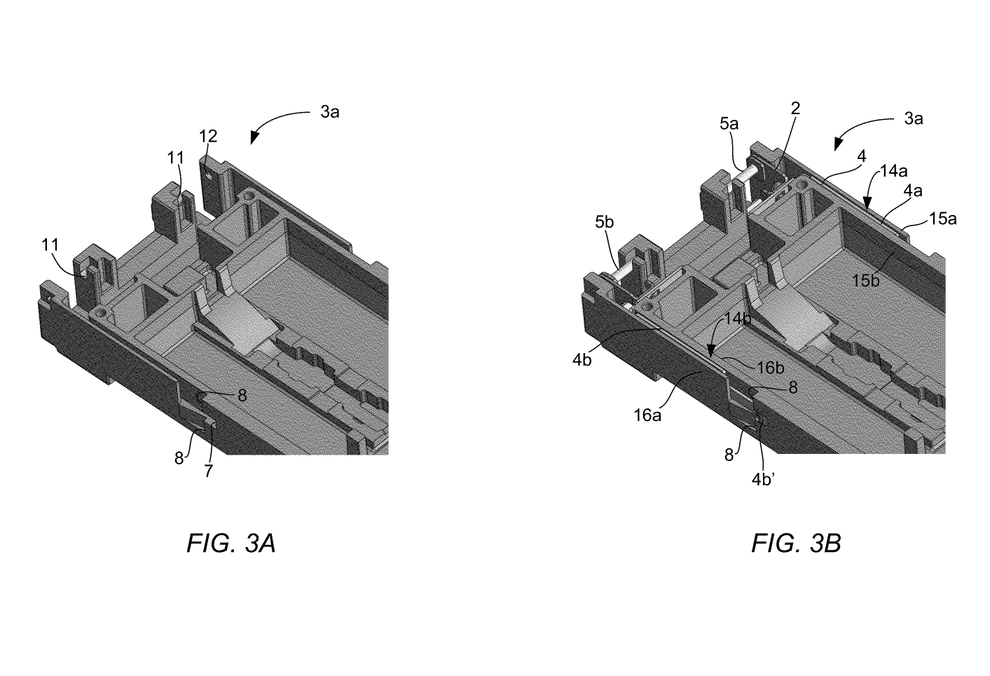

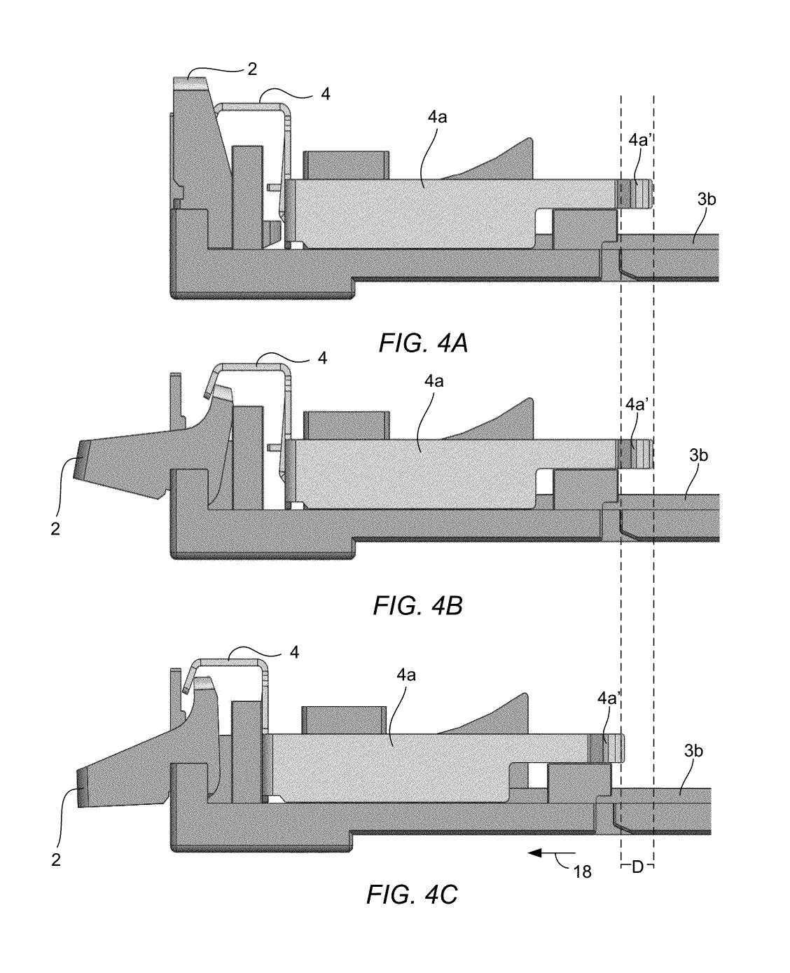

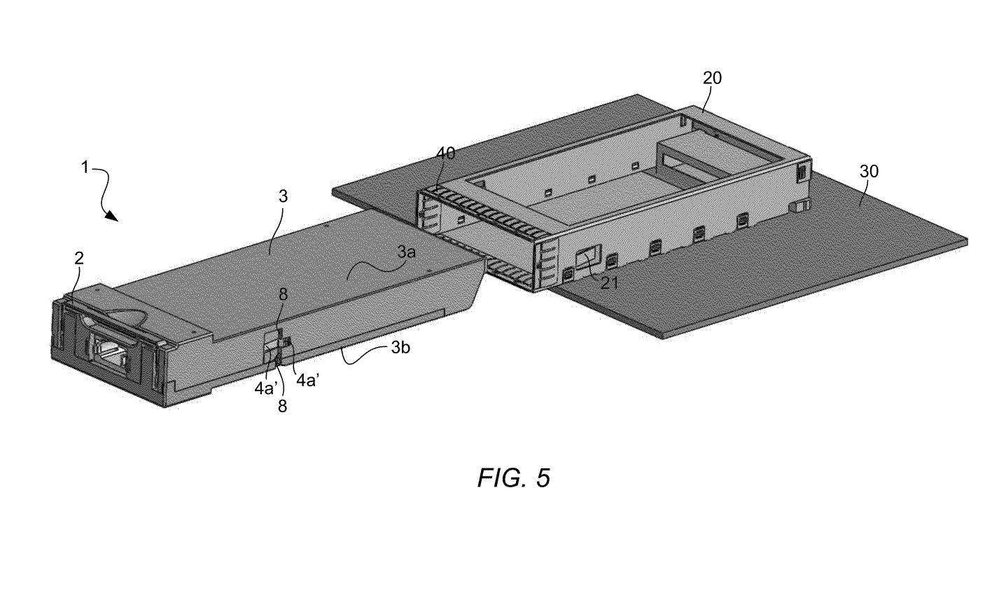

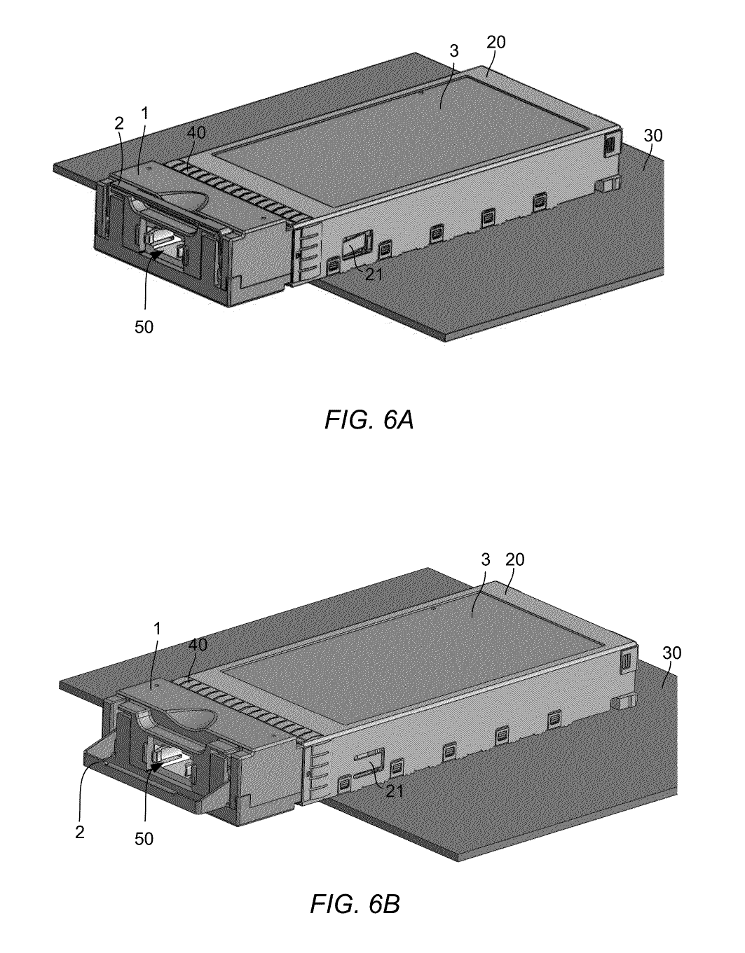

FIGS. 1A and 1B illustrate perspective views of the optical communications module 1 with the bail 2 in the latched and delatched positions, respectively. FIG. 2 illustrates a perspective view of the optical communications module shown in FIGS. 1A and 1B disassembled to show the bail 2, the upper and lower housing portions 3a and 3b, respectively, of a module housing 3, a slider 4, and dowel pins 5a and 5b. FIGS. 3A and 3B illustrate perspective views of the upper housing portion 3a shown in FIG. 2 before and after, respectively, the bail 2, the slider 4 and the dowel pins 5a and 5b have been installed in the upper housing portion 3a. FIGS. 4A-4C illustrate side plan views of the optical communications module 1 shown in FIGS. 1A and 1B with the upper housing portion 3a removed to reveal the manner in which the slider 4 moves as the bail 2 is moved from the latched position shown in FIG. 4C into the delatched position shown in FIG. 4C. FIG. 5 illustrates a perspective view of the optical communications module 1 shown in FIGS. 1A and 1B and a cage 20 into which the module 1 is about to be inserted mounted on a printed circuit board (PCB) 30. FIGS. 6A and 6B illustrate perspective views of the optical communications module 1 installed in the cage 20 shown in FIG. 5 with the bail 2 in the latched and delatched positions, respectively.

An illustrative embodiment will now be described with reference to FIGS. 1A-6B. In the perspective views shown in FIGS. 1A and 1B, one of the arms 4a of the slider 4 shown in FIG. 2 is visible. It can be seen in FIGS. 1A and 1B that the only portion of the slider arm 4a that is exposed, i.e., not encased in the housing 3, is the distal end 4a′ of the arm 4a. When the bail 2 is in the latched position shown in FIG. 1A, the distal end 4a′ of the arm 4a is seated in a pocket 7 formed in a cage latch stop 8 of the upper housing portion 3a. As the bail 2 is moved from the latched position shown in FIG. 1A to the delatched position shown in FIG. 1B, the distal end 4a′ of the arm 4a moves toward the front of the module 1 in the direction indicated by arrow 9. The distal end 4a′ of the arm 4a is formed into a hook that curves outwardly away from the module housing 3. As will be described below in more detail with reference to FIG. 6B, the hooked distal end 4a′ comes into contact with a cage latch 21 of the cage 20 to cause the cage latch 21 to disengage the cage latch stop 8 of the upper housing portion 3a. Once the cage latch 21 has disengaged the cage latch stop 8, the module 1 can be extracted from the cage 20. Although not visible in the figures, the same action occurs on the opposite side of the module housing 3 with the slider arm 4b (FIG. 2) and its hooked distal end 4b′ to cause the cage latch 21 located on the opposite side of the cage 20 to disengage the cage latch stop 8 located on the opposite side of the upper housing portion 3a.

With reference to FIG. 2, the slider 4 has a yoke 4c that extends between proximal ends 4a″ and 4b″ of the slider arms 4a and 4b, respectively, and that is integrally formed therewith. Downwardly-curving fingers 4d and 4e extend from a front side of the yoke 4c for engaging the bail 2. The bail 2 has first and second ends 2a and 2b, respectively, that have first and second cylindrically-shaped openings 2a′ and 2b′ formed therein through which the dowel pins 5a and 5b pass, respectively. A cross member 2c of the bail 2 extends between the first and second ends 2a and 2b and acts as a handle for a user to grip with a finger when operating the bail 2. The first and second ends 2a and 2b of the bail 2 have first and second inwardly-directed U-shaped features 2d and 2e formed on them, respectively. The first and second features 2d and 2e are shaped, sized and positioned to engage the fingers 4d and 4e, respectively, of the slider 4 such that movement of the bail 2 to the delatching position translates into movement of the slider 4, as will be described below in more detail with reference to FIGS. 4A-4C.

With reference to FIGS. 2, 3A and 3B, the lower surfaces of the upper housing portion 3a that come into contact with the bail 2 and the slider 4 can be seen. As shown in FIG. 3B, the bail 2 and the slider 4 are mounted in the upper housing portion, although the bail cross member 2c and the hooked distal ends 4a′ and 4b′ of the arms 4a and 4b, respectively, are exposed. All other portions of the bail 2 and the slider 4 are internal to the upper housing portion 3a. The dowel pins 5a and 5b pass thru the openings 2a′ and 2b′ (FIG. 2) formed in the ends 2a and 2b (FIG. 2), respectively, of the bail 2. First ends of the dowel pins 5a and 5b are seated in U-shaped openings 11 formed in the upper housing portion 3a and second ends of the dowel pins 5a and 5b are seated in holes 12 formed in the upper housing portion 3a, as shown in FIG. 3B. The holes 12 are complementary in shape and size to the shape and size of the second ends of the dowel pins 5a and 5b. When the upper and lower housing portions 3a and 3b are secured together, U-shaped openings 13 formed in interior surfaces of the lower housing portion 3b (FIG. 2) come into contact with the pins 5a and 5b from the side of the housing 3 opposite U-shaped openings 11, thereby capturing the dowel pins 5a and 5b in position within the housing 3. The combination of the U-shaped openings 11 and 13, the holes 12, and other internal surfaces of the upper and lower housing portions 3a and 3b maintains the pins 5a and 5b in position within the housing 3 while allowing them to rotate about their axes and move slightly in their axial directions.

The dowel pins 5a and 5b and the configuration by which they are held in place in the housing 3 provide a much more robust solution than the press-fitted pins of the known arrangement. By using the dowel pins 5a and 5b instead of press-fitted pins for this purpose, excessive forces that are exerted on the dowel pins 5a and 5b will be transferred to the housing 3, which makes it less likely that the bail 2 and the slider 4 will be dislodged from the module housing 3. In addition, the new arrangement makes it virtually impossible for the pins 5a and 5b to come loose in the event that excessive forces are applied to the bail 2 during the extraction process. The bail 2 pivots or rotates about the pins 5a and 5b between the latched position shown in FIG. 1A and the delatched position shown in FIG. 1B. Thus, the pins 5a and 5b perform the same function as the press-fitted pins of the known arrangement, but they are held in place in the housing 3 in a way that prevents them from being compromised and in a way that prevents the bail 2 and the slider 4 from being dislodged.

With reference to FIG. 3B, it can be seen that the slider arms 4a and 4b are disposed in respective channel grooves 14a and 14b formed in the upper housing portion 3a. The channel groove 14a is formed by a narrow spacing that exists in between an outer side wall 15a of the upper housing portion 3a and an inner side wall 15b of the upper housing portion 3a. Likewise, the channel groove 14b is formed by a narrow spacing that exists in between an outer side wall 16a of the upper housing portion 3a and an inner side wall 16b of the upper housing portion 3a. The widths of the grooves 14a and 14b are slightly greater than the widths of the slider arms 4a and 4b, respectively, (FIG. 2) to allow the slider arms 4a and 4b to slide within the grooves 14a and 14b during the delatching process. In accordance with this illustrative embodiment, the depths of the grooves 14a and 14b are slightly greater than the heights of the slider arms 4a and 4b (FIG. 2) so that the slider arms 4a and 4b. Therefore, all but the distal ends 4a′ and 4b′ of the slider arms 4a and 4b are encased inside of the upper housing portion 3a.

There are multiple advantages to encasing all but the distal ends 4a′ and 4b′ of the slider arms 4a and 4b within the housing 3. One of the advantages is that it increases the rigidity of the slider 4 compared to known solutions where the slider arms are exposed along the outer side surfaces of the module housing. The increased rigidity prevents the latching/delatching mechanism from being dislodged from the module housing 3 and protects the latching/delatching mechanism from being damaged by external factors, thereby improving reliability and longevity. Another advantage of encasing most of the slider arms 4a and 4b within the housing 3 is that it prevents the slider arms 4a and 4b from coming into contact with the EMI shield 40 of the cage 20 when the module 1 is inserted into and retracted from the cage 20, as will be described below in more detail with reference to FIG. 5.

There is also an advantage to forming the cage latch stops 8 in the upper housing portion 3a. In known pluggable modules of the type described above, typically one cage latch stop is formed on the upper housing portion and the other cage latch stop is formed on the lower housing portion. Because of manufacturing tolerances, the upper and lower housing portions may not be precisely aligned at their interface when they are assembled, which can result in the cage latch stops on the upper and lower housing portions not being precisely aligned. This, in turn, can result in the module not latching properly within the cage, which can lead to other problems. Because both cage latch stops 8 are formed in the upper housing portion 3a, precise alignment of the cage latch stops 8 with one another is ensured. The upper and lower housing portions 3a and 3b are typically made by die casting zinc, and therefore can be made to meet very tight tolerances. The housing portions 3a and 3b, however, could be made of other materials and by other processes, as will be understood by those of skill in the art in view of the description being provided herein. The bail 2 and the slider 4 are typically made of a metallic material such as sheet metal or stainless steel, for example.

With reference to FIGS. 4A-4C, the distance, D, that the distal end 4a′ of the slider arm 4a travels during the delatching process can be seen. As the bail 2 is rotated from the latched position shown in FIG. 4A through the partially latched position shown in FIG. 4B to the fully-delatched position shown in FIG. 4C, the distal end 4a′ of the slider arm 4a travels in the direction indicated by arrow 18. With reference to FIGS. 5-6B, as the distal ends 4a′ and 4b′ of the slider arms 4a and 4b, respectively, travel in this direction, they come into contact with inner surfaces of the respective cage latches 21 and push outwardly on the cage latches 21. This causes the cage latches 21 to deflect outwardly away from the respective outer side walls of the module housing 3 until the cage latches 21 become disengaged from the respective cage latch stops 8 (FIG. 6B), allowing the module 1 to be extracted from the cage 20.

The cage 20 has an EMI gasket 40 on the inner and outer surfaces of the cage opening. Such EMI gaskets are commonly used in cages that are adapted to mate with pluggable optical communications modules. As indicated above, the known latching/delatching mechanisms come into contact with the portions of the EMI gasket that are disposed in the inner surfaces of the cage opening and can cause them to peel or otherwise become damaged. Because all but the distal ends 4a′ and 4b′ of the slider arms 4a and 4b are encased within the housing 3, the slider 4 does not come into contact with the EMI gasket 40 when the module 1 is inserted into and extracted from the cage 20. This is an additional benefit that is realized by encasing all or most of the slider 4 within the housing 3. Although the distal ends 4a′ and 4b′ of the slider arms 4a and 4b are outside of the housing 3, they are within a recess of the upper housing portion 3a and therefore only make contact with the respective cage latches 21, which project inwardly from the respective side walls of the cage 20.

With reference again to FIGS. 6A and 6B, the module housing 3 contains electrical, optical and optoelectronic components (not shown). The module housing 3 has a receptacle 50 formed therein for mating with a plug or connector of an optical fiber cable (not shown). The module housing typically also includes a PCB (not shown) or the like on which the electrical, optical and optoelectronic components are mounted. The lower surface of the PCB of the module housing 3 has electrical contacts thereon that connect with electrical contacts of the PCB 30 when the module 1 is fully inserted into the cage 20. Through these electrical connections, electrical connections are made between the PCB 30 and the electrical circuitry of the module 1.

It should be noted that the invention has been described with reference to illustrative embodiments and that the invention is not limited to these embodiments. Those skilled in the art will understand the manner in which modifications can be made to the illustrative embodiments and that all such modifications are within the scope of the invention. For example, although the module housing 3 and the slider 4 have been described as having particular configurations, persons skilled in the art will understand the manner in which these configurations may be modified while still achieving the goals of the invention. For example, while the upper housing portion 3a has been described as having outer side walls 15a/16a and inner side walls 15b/16b in order to form the channel grooves 14a and 14b, the slider arms 4a and 4b could be encased within the module housing 3 in other ways. These and other modifications may be made to the embodiments described herein and all such modified embodiments are also within the scope of the invention, as will be understood by persons skilled in the art.

1. A pluggable optical communications module comprising:
a module housing having a receptacle formed therein for receiving an end of an optical fiber cable, the module housing having at least a top, a bottom, a first side and a second side, the top and bottom being interconnected by the first and second sides such that the top, the bottom, the first side, and the second side form an encasement, wherein components of the module are housed in the encasement, and wherein the first and second sides have first and second cage latch stops thereon, respectively; and
a latching/delatching mechanism secured to the module housing, the latching/delatching mechanism including at least a bail and a slider, the bail being pivotally coupled with the module housing to allow the bail to rotate between a latched position and a delatched position, the slider including at least first and second slider arms and a yoke, wherein the yoke is joined with proximal ends of the first and second slider arms and is positioned to mechanically couple with the bail as the bail is pivoted from the latched position to the delatched position, the first slider arm extending along at least a portion of the first side of the module housing and being partially encased within the encasement, wherein at least a distal end of the first slider arm is outside of the encasement, the second slider arm extending along at least a portion of the second side of the module housing and being partially encased within the encasement, wherein at least a distal end of the second slider arm is outside of the encasement, wherein the distal ends of the first and second slider arms include first and second hook features, respectively, that curve outwardly relative to the first and second sides, respectively, of the module housing.

2. The pluggable optical communications module of claim 1, the first side of the module housing comprises a first inner side wall and a first outer side wall that are separated by a small gap to form a first channel groove, and wherein the second side of the module housing comprises a second inner side wall and a second outer side wall that are separated by a gap to form a second channel groove, and wherein the partially-encased first slider arm is disposed in the first channel groove and wherein the partially-encased second slider arm is disposed in the second channel groove, the first and second channel grooves having widths that are wider than widths of the partially-encased first and second slider arms to allow the partially-encased first and second slider arms to travel within the first and second channel grooves, respectively, as the bail is pivoted from the latched position to the delatched position.

3. The pluggable optical communications module of claim 2, wherein the first and second slider arms have respective heights that are less than respective depths of the first and second channel grooves.

4. The pluggable optical communications module of claim 2, wherein the module is adapted to be received in an opening of a cage, the cage having a top, a bottom, a first side and a second side, the top and bottom of the cage being interconnected by the first and second sides of the cage such that the top, the bottom, the first side, and the second side of the cage define the cage opening, and wherein first and second cage latches are disposed on the first and second sides of the cage, respectively, within the opening for engaging the first and second cage latch stops, respectively, and wherein when the bail is pivoted from the latched position to the delatched position, the bail mechanical couples with the slider yoke to exert a force on the slider that pulls the first and second slider arms in a delatching direction to cause the first and second hook features to press outwardly against the first and second cage latches, respectively, thereby disengaging the first and second cage latches from the first and second cage latch stops, respectively.

5. The pluggable optical communications module of claim 2, further comprising:
first and second dowel pins that mechanically couple the bail to the module housing, wherein the dowel pins allow the bail to be pivoted from the latched position into the delatched position.

6. The pluggable optical communications module of claim 5, wherein first ends of the first and second dowel pins are rotationally coupled to the module housing such that the dowel pins are allowed to rotate about respective axes of the dowel pins, and wherein the first and second dowel pins pass thru first and second openings, respectively, formed in first and second ends, respectively, of the bail.

7. The pluggable optical communications module of claim 2, wherein the module housing includes an upper housing portion and a lower housing portion, the upper housing portion comprising the top of the module housing, the lower housing portion comprising the bottom of the module housing, the upper housing portion and the lower housing portion each having first sides and second sides, wherein the first sides of the upper and lower housing portions interface to form the first side of the module housing, and wherein the second sides of the upper and lower housing portions interface to form the second side of the module housing.

8. The pluggable optical communications module of claim 7, wherein the first and second slider arms extend along respective portions of the first and second sides, respectively, of the upper housing portion.

9. The pluggable optical communications module of claim 8, wherein the first and second cage latch stops are disposed on the first and second sides, respectively, of the upper housing portion.

10. An optical communications assembly comprising:
a cage having a top, a bottom, a first side and a second side, the top and bottom of the cage being interconnected by the first and second sides of the cage such that the top, the bottom, the first side, and the second side of the cage define a cage opening, and wherein first and second cage latches are disposed on the first and second sides of the cage, respectively, within the opening; and
an optical communications module disposed in the cage opening, the module comprising:
a module housing having a receptacle formed therein for receiving an end of an optical fiber cable, the module housing having at least a top, a bottom, a first side and a second side, the top and bottom being interconnected by the first and second sides such that the top, the bottom, the first side, and the second side form an encasement, wherein components of the module are housed in the encasement, and wherein the first and second sides have first and second cage latch stops thereon, respectively, that are engaged with the first and second cage latches, respectively; and
a latching/delatching mechanism secured to the module housing, the latching/delatching mechanism including at least a bail and a slider, the bail being pivotally coupled with the module housing to allow the bail to rotate between a latched position and a delatched position, the slider including at least first and second slider arms and a yoke, wherein the yoke is joined with proximal ends of the first and second slider arms and is positioned to mechanically couple with the bail as the bail is pivoted from the latched position to the delatched position, the first slider arm extending along at least a portion of the first side of the module housing and being partially encased within the encasement, wherein at least a distal end of the first slider arm is outside of the encasement, the second slider arm extending along at least a portion of the second side of the module housing and being partially encased within the encasement, wherein at least a distal end of the second slider arm is outside of the encasement, wherein the distal ends of the first and second slider arms include first and second hook features, respectively, that curve outwardly relative to the first and second sides, respectively, of the module housing.

11. The optical communications assembly of claim 10, wherein if the bail is pivoted from the latched position to the delatched position, the bail mechanical couples with the slider yoke to exert a force on the slider that pulls the first and second slider arms in a delatching direction to cause the first and second hook features to press outwardly against the first and second cage latches, respectively, thereby disengaging the first and second cage latches from the first and second cage latch stops, respectively.

12. The optical communications assembly of claim 10, the first side of the module housing comprises a first inner side wall and a first outer side wall that are separated by a small gap to form a first channel groove, and wherein the second side of the module housing comprises a second inner side wall and a second outer side wall that are separated by a gap to form a second channel groove, and wherein the partially-encased first slider arm is disposed in the first channel groove and wherein the partially-encased second slider arm is disposed in the second channel groove, the first and second channel grooves having widths that are wider than widths of the partially-encased first and second slider arms to allow the partially-encased first and second slider arms to travel within the first and second channel grooves, respectively, as the bail is pivoted from the latched position to the delatched position.

13. The optical communications assembly of claim 12, wherein the first and second slider arms have respective heights that are less than respective depths of the first and second channel grooves.

14. The optical communications assembly of claim 12, wherein the module is adapted to be received in an opening of a cage, the cage having a top, a bottom, a first side and a second side, the top and bottom of the cage being interconnected by the first and second sides of the cage such that the top, the bottom, the first side, and the second side of the cage define the cage opening, and wherein first and second cage latches are disposed on the first and second sides of the cage, respectively, within the opening for engaging the first and second cage latch stops, respectively, and wherein when the bail is pivoted from the latched position to the delatched position, the bail mechanical couples with the slider yoke to exert a force on the slider that pulls the first and second slider arms in a delatching direction to cause the first and second hook features to press outwardly against the first and second cage latches, respectively, thereby disengaging the first and second cage latches from the first and second cage latch stops, respectively.

15. The optical communications assembly of claim 12, further comprising:
first and second dowel pins that mechanically couple the bail to the module housing, wherein the dowel pins allow the bail to be pivoted from the latched position into the delatched position.

16. The optical communications assembly of claim 15, wherein first ends of the first and second dowel pins are rotationally coupled to the module housing such that the dowel pins are allowed to rotate about respective axes of the dowel pins, and wherein the first and second dowel pins pass thru first and second openings, respectively, formed in first and second ends, respectively, of the bail.

17. The optical communications assembly of claim 12, wherein the module housing includes an upper housing portion and a lower housing portion, the upper housing portion comprising the top of the module housing, the lower housing portion comprising the bottom of the module housing, the upper housing portion and the lower housing portion each having first sides and second sides, wherein the first sides of the upper and lower housing portions interface to form the first side of the module housing, and wherein the second sides of the upper and lower housing portions interface to form the second side of the module housing.

18. The optical communications assembly of claim 17, wherein the first and second slider arms extend along respective portions of the first and second sides, respectively, of the upper housing portion.

19. The optical communications assembly of claim 18, wherein the first and second cage latch stops are disposed on the first and second sides, respectively, of the upper housing portion.

20. A pluggable optical communications module comprising:
a module housing having a receptacle formed therein for receiving an end of an optical fiber cable, the module housing having at least a top, a bottom, a first side and a second side, the top and bottom being interconnected by the first and second sides such that the top, the bottom, the first side, and the second side form an encasement, wherein components of the module are housed in the encasement, and wherein the first and second sides have first and second cage latch stops thereon, respectively, the first side of the module housing comprises a first inner side wall and a first outer side wall that are separated by a small gap to form a first channel groove, and wherein the second side of the module housing comprises a second inner side wall and a second outer side wall that are separated by a gap to form a second channel groove; and
a latching/delatching mechanism secured to the module housing, the latching/delatching mechanism including at least a bail and a slider, the bail being pivotally coupled with the module housing to allow the bail to rotate between a latched position and a delatched position, the slider including at least first and second slider arms and a yoke, wherein the yoke is joined with proximal ends of the first and second slider arms and is positioned to mechanically couple with the bail as the bail is pivoted from the latched position to the delatched position, the first slider arm extending along at least a portion of the first side of the module housing and being partially disposed in the first channel groove, wherein at least a distal end of the first slider arm is outside of the first channel groove, the second slider arm extending along at least a portion of the second side of the module housing and being partially disposed in the second channel groove, wherein at least a distal end of the second slider arm is outside of the second channel groove, wherein the distal ends of the first and second slider arms include first and second hook features, respectively, that curve outwardly relative to the first and second sides, respectively, of the module housing.

21. The pluggable optical communications module of claim 20, wherein the first and second channel grooves having widths that are wider than widths of the portions of the first and second slider arms that are disposed in the first and second channel grooves, respectively, to allow the portions of the first and second slider arms to travel within the first and second channel grooves, respectively, as the bail is pivoted from the latched position to the delatched position.
